(19) United States
(12) Patent Application Publication
(10) Pub. No.: US 2002/0036889 A1
(43) Pub. Date: Mar. 28, 2002

(54) Housing for an electronic apparatus and a method for its assembly

(76) Inventors: Fernando Ruiz-Gomez, Sollentuna (SE); Feridon Razi, Huddinge (SE)

Correspondence Address: HARNESS, DICKEY & PIERCE, P.L.C., 5445 CORPORATE DRIVE, SUITE 400, TROY, MI, 48098, US

(21) Appl. No.: 09/948,862

(22) Filed: Sep. 7, 2001

(30) Foreign Application Priority Data
Sep. 8, 2000 (SE) 0003189-9

(51) Int. Cl. H05K 7/20

(52) U.S. Cl. 361/695

(57) ABSTRACT

A housing for an electronic apparatus having heat generating components, such as a rectifier, comprises a bottom panel (4a), at least one side panel (4c, 4d, 4e, 4f) and a lid (4b). According to the invention, the whole housing is adapted do constitute a heat sink.

### TECHNICAL FIELD OF THE INVENTION

The present invention relates to a housing for an electronic apparatus having heat generating components, such as a rectifier, comprising a bottom panel, at least one side panel and a lid. This Application claims priority to Swedish Patent Application No. 0003189-9 filed on Sep. 8, 2000, the entire disclosure of which is incorporated by reference herein. The invention also relates to an electronic apparatus having heat generating components, such as a rectifier, comprising such a housing and a printed circuit board, and to a method of assembling such an electronic apparatus.

Such a housing as well as such an electronic apparatus and methods of assembling such electronic apparatuses are generally known in the art and are marketed by Emerson Energy Systems AB.

### OBJECT OF THE INVENTION

The object of the invention is to provide a housing and an electronic apparatus having improved heat transfer properties and an improved method of assembling such an electronic apparatus.

### SUMMARY OF THE INVENTION

This has been achieved by a housing and an electronic apparatus of the initially defined kind, wherein the whole housing is adapted do constitute a heat sink.

It has also been achieved by a method of the initially defined kind, including selecting a housing completely made of metal and comprising a lid and a first unit having a bottom panel and at least one side panel, providing a printed circuit board with components, providing said first unit with said printed circuit board, providing said first unit with a lid, such that it covers the printed circuit board. Hereby is achieved efficient cooling of all components in the housing.

Preferably, said bottom panel and said at least one side panel are formed in metal as an integrated first unit, wherein said first unit is adapted to receive said lid formed in metal and constituting a second unit. Hereby, a housing constituted by solely two components is achieved.

Suitably, at least said first unit is provided with integrated surface enlargements formed in one piece together with the rest of said first unit. Hereby, separate mounting of surface enlargements into the housing is avoided.

Advantageously, said surface enlargements protrude from the interior surface of the first unit into the interior of the housing.

Preferably, at least one air inlet opening is provided for allowing cooling air to enter the housing, and wherein at least one of said surface enlargements is associated with at least one opening for allowing air to pass through from the interior to the exterior of the housing. Hereby, cooling of the components by natural convection is achieved.

Suitably, said air inlet opening is adapted to receive a fan for drawing air through said air inlet opening and for creating a pressure higher than the atmospheric pressure inside the housing. Hereby, cooling of the components by forced convection is achieved.

Preferably, the housing it is made of an aluminium alloy. Hereby is achieved an inexpensive manufacturing of the housing and that heat transfer is allowed through the whole housing to the exterior thereof.

Preferably, said bottom panel is substantially rectangular forming four edges, and wherein a side panel is formed in one piece with the bottom panel along each edge, and wherein said side panels are formed as one piece. Hereby, the first unit is formed as a unitary piece.

### DRAWING SUMMARY

In the following, the invention will be described in more detail with reference to the accompanying drawings, in which

FIG. 1 is a perspective view of a three phase rectifier provided with heat sink bodies,

FIG. 2 is an exploded view of the rectifier shown in FIG. 1,

FIG. 3 is a magnification of FIG. 2,

FIG. 4 illustrates the heat sink body shown in FIG. 1 and a spring device,

FIG. 5a is a perspective view of the rectifier shown in FIG. 1, but from the opposite direction,

FIG. 5b is a plan view of the rectifier shown in FIG. 5a

FIG. 5c is a schematic representation of the compression of a spring device,

FIGS. 6a-6d illustrate different embodiments of spring devices,

FIGS. 7a-7c illustrate different embodiments of fins of the heat sink bodies shown in FIG. 1

FIG. 8 illustrates air flow through the rectifier shown in FIGS. 1-7c

FIGS. 9a-9d illustrate a one phase rectifier, and

FIG. 10 illustrates air flow through the rectifier of FIGS. 9a-9d.

### DETAILED DESCRIPTION

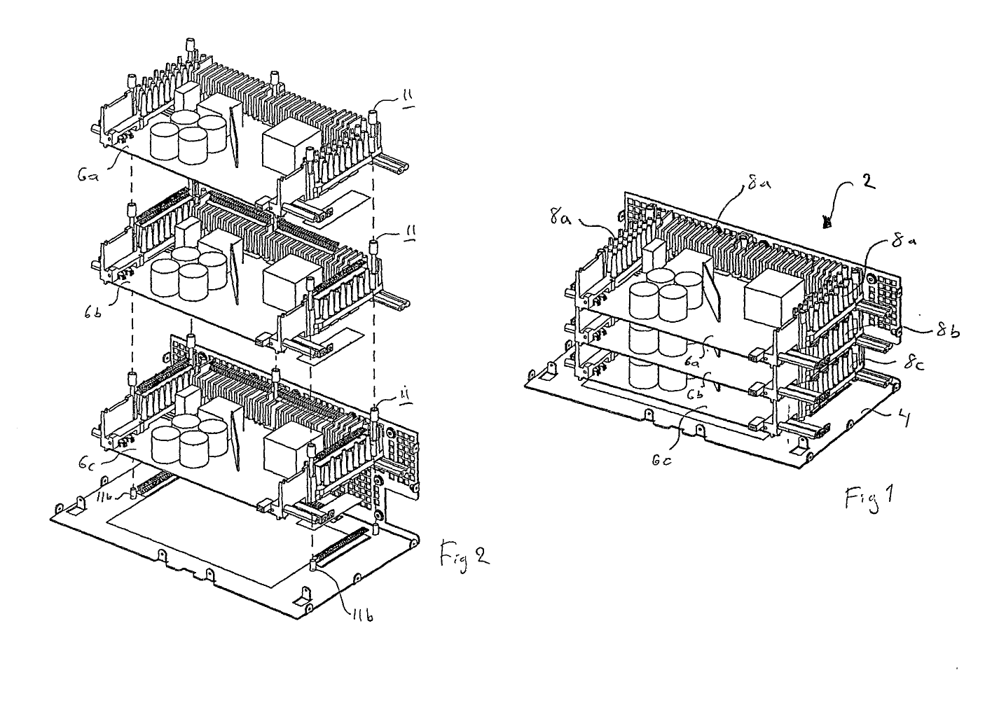

FIG. 1 shows a rectifier 2 mounted in a housing 4, of which the top and three of the side panels have been omitted for reasons of clarity.

The rectifier 2 has three layers of printed circuit boards 6a, 6b, 6c, each provided with heat a sink body 8a, 8b and 8c.

The rectifier 2 is a three phase rectifier. Accordingly, each layer is a rectifier for one of the three phases.

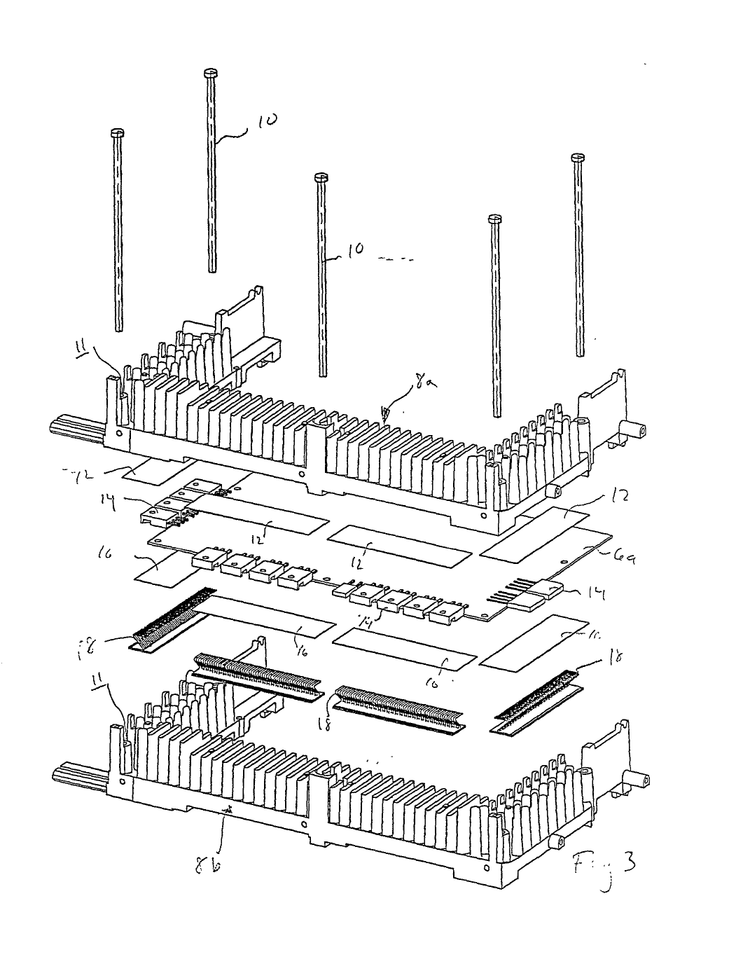

FIG. 2 shows in an exploded view how the printed circuit boards 6a, 6b, 6c have been stacked on top of one another to form the compact unit shown in FIG. 1.

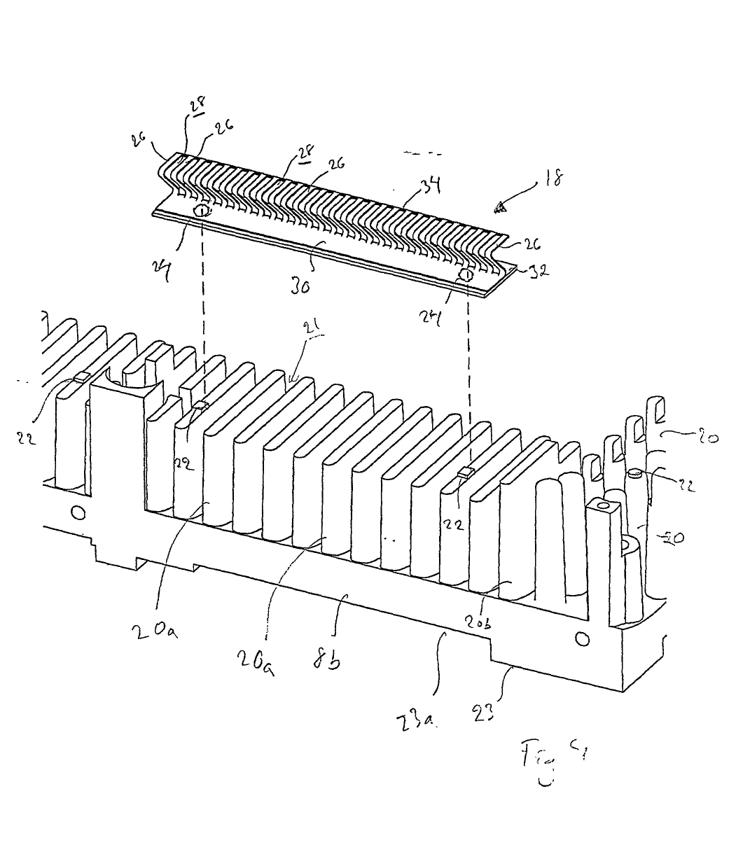

FIG. 3 shows in an exploded view from above: Screws 10 to be introduced into through holes 11a 11b in each heat sink body and to be fastened in nuts 11b arrannged on the bottom of the housing 4, for the assembly of the three layers of printed circuit boards 6a, 6b, 6c shown in FIGS. 1 and 2. Thereafter in consecutive order: The uppermost heat sink body 8a, upper insulation strips 12, the uppermost printed circuit board 6a, provided with electronic components 14 to be cooled by the heat sink body 8a, lower insulation strips 16, four spring devices 18 and the middle heat sink body 8b.

FIG. 4 shows the heat sink body 8b provided with a plurality of cooling fins or pins 20a, 20b, divided by an air gap 21. On top of a pair of fins there is provided a protrusion 22. The thermal insulation body is provided with a pair of openings 24, adapted to receive the corresponding pair of protrusions 22. The fins 20a supporting the spring device 18 are lower than the ones surrounding 20b the spring device 18. In fact, the surrounding fins of the heat sink body 8c are adapted to support a portion of the lower surface 23 of the heat sink body 8b. In the same manner, the surrounding fins of the heat sink body 8b are adapted to support the heat sink body 8a, whereas the surrounding fins of the heat sink body 8a are adapted to support the not shown lid.

The lower surface 23 of each heat sink body 8a, 8b, 8c is furthermore arranged with a cut-out 23a for leaving space for each spring device 18 and the components 14.

Of course, instead of providing the cut-out 23a and the lower fins 20a for leaving space for each spring device 18 and the components 14, the space could have been formed by providing a deeper cut-out in the lower surface 23, thereby providing fins of equal length.

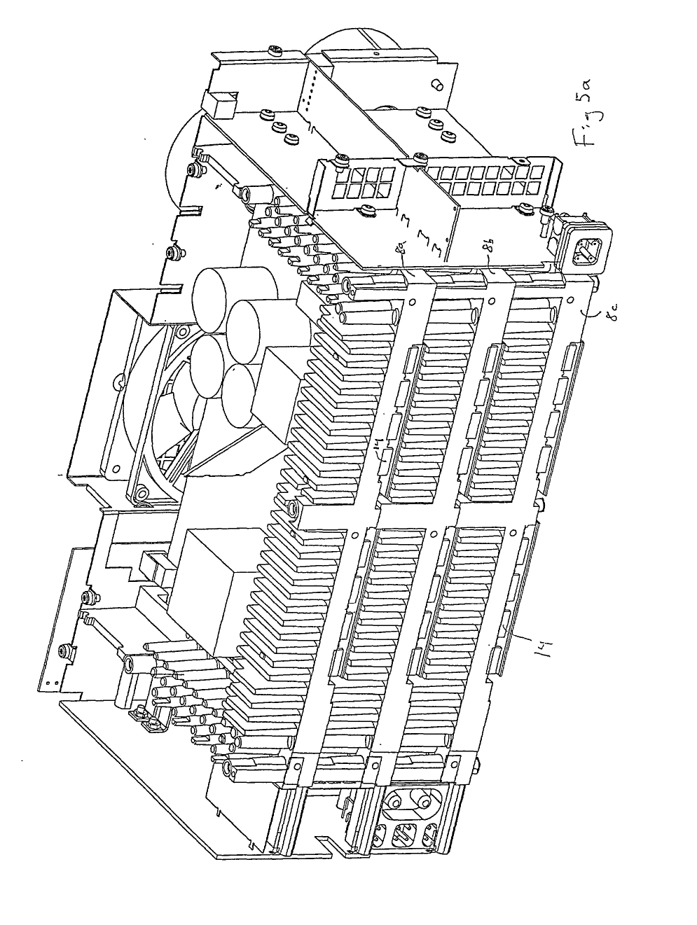

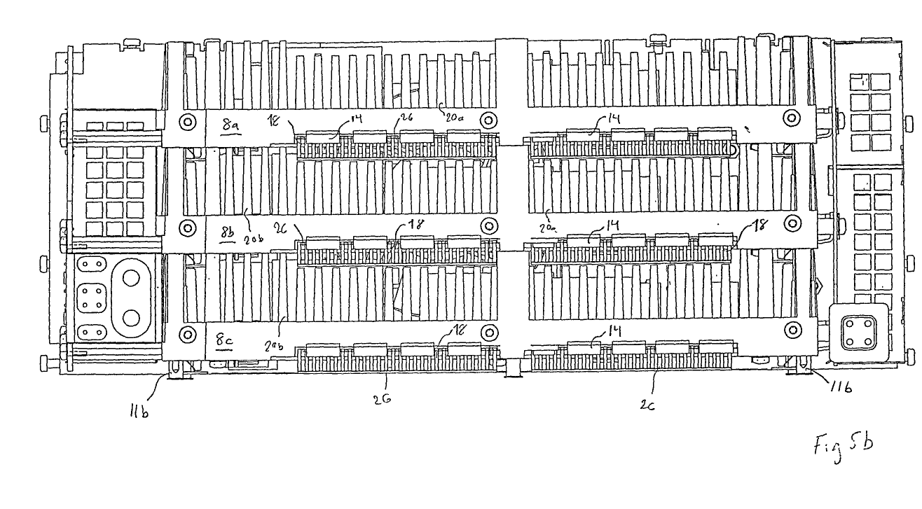

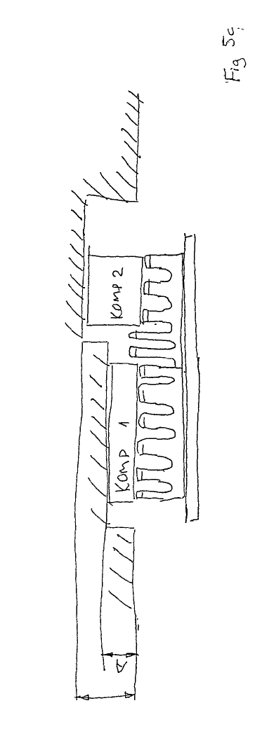

Alternatively, it could have been possible to provide an even lower surface 23, thereby providing even lower fins 20a. However in that case, there would be no space for spring devices 18 and components underneath the lowest heat sink body 8c (cf. FIG. 5b).

The cross-section of the spring device 18 has the form of a Z making it resilient. The spring device 18 is furthermore made of a resilient material, such as spring steel, but could as well be made of e.g. a plastic material as the spring device 18 itself is not intended to substantially contribute to heat transfer, but to provide a springing effect, which will be discussed below. It should be noted in this context that spring steel has bad heat transfer properties.

The spring device 18 is provided with strips 26 divided by slits 28. The strips 26 are joined at one end by an elongated portion 30 attached to a plate 32 of metal or plastic, transversal to the strips 26, and at the other end by an elongated member 34.

FIG. 5a shows the rectifier 2 from the opposite direction, compared to in FIG. 1, and FIG. 5b is a front view of the rectifier 2 shown in FIG. 5a. A fan 36 for drawing air through the rectifier is arranged at the end of the housing where no heat sink body is provided.

During assembly, the spring devices 18 are placed on the bottom of the housing 4. On top of the spring devices 18, lower insulation strips 12 are arranged. Thereafter, the printed circuit board 6c is arranged such that the components 14 mounted thereon contact the strips 26 of a corresponding spring device 18. On top of the components 14, the upper insulation strips 16 are arranged. The heat sink body 8c is then placed on top of the printed circuit board 6c, such that the components 14 thereof contact the heat sink 8c via the upper insulation strips 12.

On the lower fins 20a of the heat sink body 8c, spring devices 18 are arranged, on top of which lower insulation strips 16, components mounted on printed circuit board 6b, upper insulation strips 14 and heat sink body 8b. On top of the lower fins 20a, spring devices etc are arranged in a corresponding manner.

The uppermost heat sink body 8a is provided with lower fins 20a, but no spring device etc. is arranged there. The reason for the provision of lower fins 20a on the heat sink body 8a is simply to avoid high production costs caused by the use of differently shaped heat sink bodies.

The screws 10 are now inserted through the holes 11a and tightened by means of the nuts 11b. During tightening thereof, the strips 26 of the spring devices 18 will be pressed together, in particular the strips 26 bearing against the components 14.

The strips 26 are intended to be compressed to a predetermined extent, in order to provide a predetermined pressure on the components 14, such that a desired cooling effect from the heat sink body is achieved. Thus, as can be seen in FIG. 5c, if a component is thicker than the average component, the cut-out 23a in the lower surface 23 of the heat sink body arranged on top of that component, must be made deeper than the rest of the cut-out. The same occurs if a component does not have the same lateral extension, i.e. does not compress the same number of strips 26.

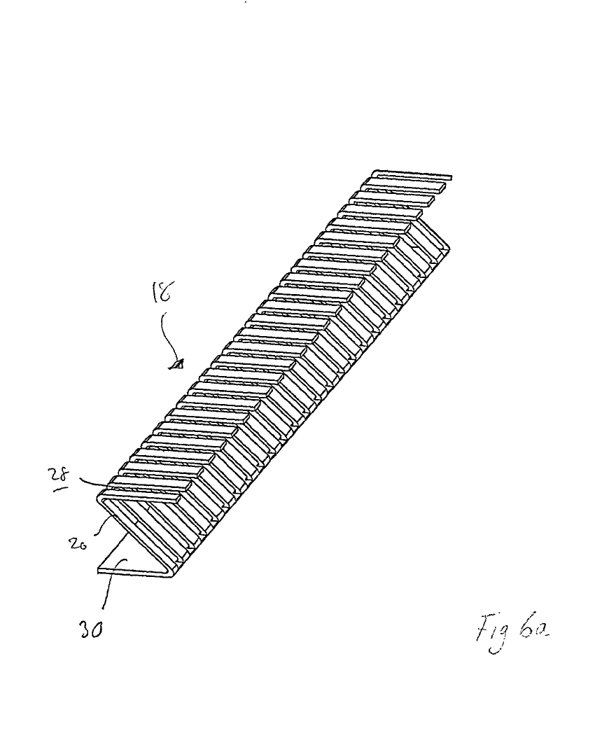

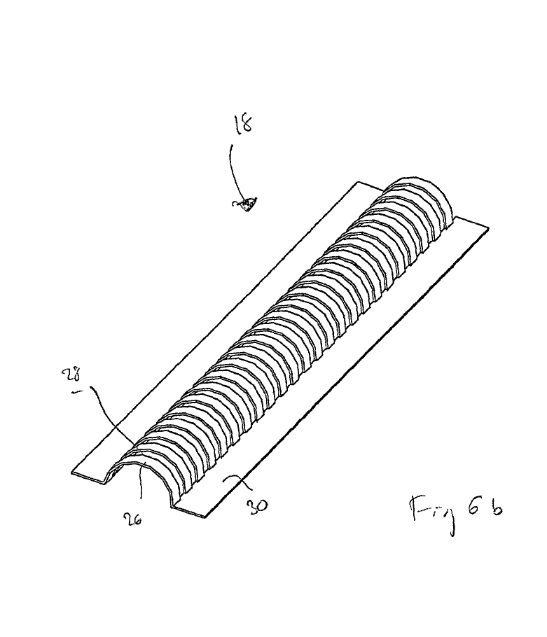

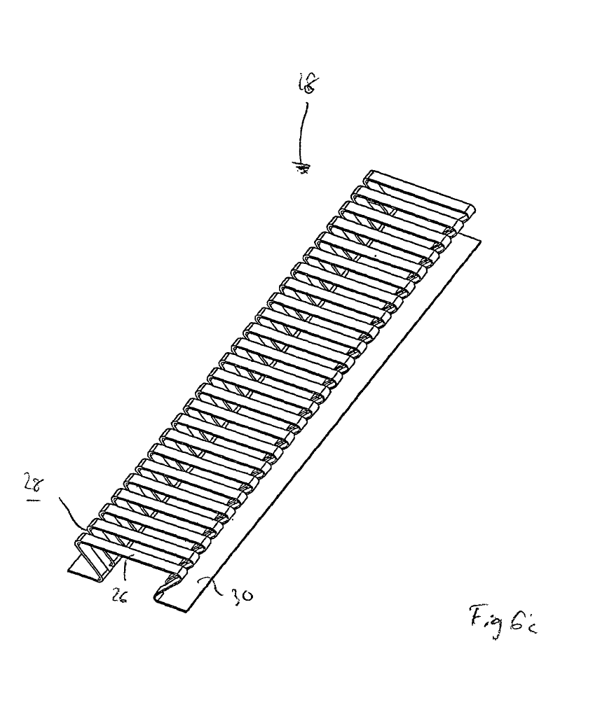

FIG. 6a shows an alternative embodiment of the spring device 18, according to which embodiment the strips 26 divided by slits 28 have free ends at one end, i.e. no second elongated portion 34 is provided.

FIG. 6b shows another alternative embodiment, according to which the strips 26 divided by slits 28 have a semi-circular cross-section.

FIG. 6c shows yet another alternative embodiment, according to which the strips 26 divided by slits 28 have the cross-section of a pair of reversed Z.

Furthermore, in FIGS. 6a-6c, no plate 32 has been shown, even though the plate 32 may be provided also in this embodiment.

FIG. 6d shows another alternative embodiment of the spring device 18. The strips 26 divided by slits 28 are unevenly distributed over the elongated portion 30. The strips 26 are not inter-connected, as is also the case in the spring device shown in FIG. 6a. This kind of spring device is advantageous as is can be completely adapted to a particular set-up of components, i.e. with different lateral dimensions and thicknesses.

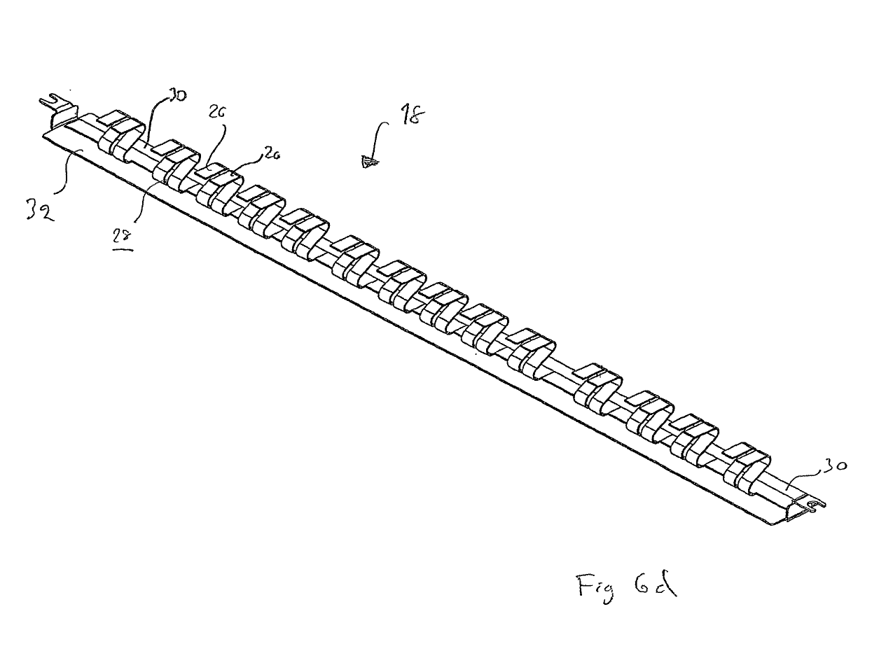

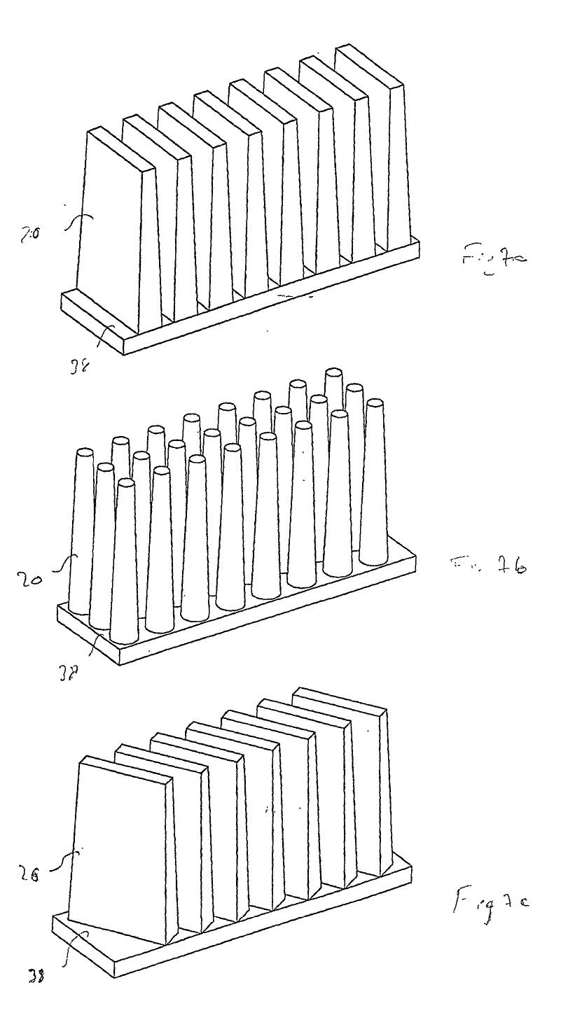

FIGS. 7a, 7b and 7c show alternative forms and distributions of the cooling fins or pins 20. In FIG. 7a, the fins have a rectangular cross-section, and are distributed in a parallel relation ship across the elongated extension of a support plate 38. In FIG. 7b, they have a circular cross-section and are evenly distributed over the support plate 38. In FIG. 7c, they have a rectangular cross-section, but they are arranged at an angle to the elongated extension of said support plate 38.

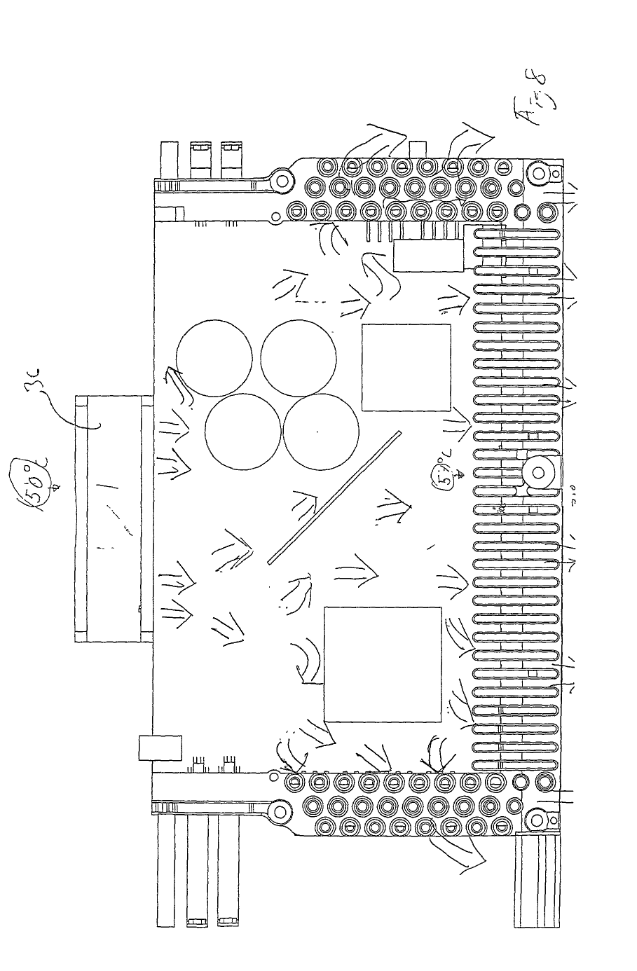

In FIG. 8, one layer of printed circuit board with mounted heat sink body is shown. The fan 36 draws air of about 50° C. into the housing and over components not contacted by the heat sink bodies 8a, 8b 8c. The temperature has thus risen to about 57° C. when entering the spaces 21 between the fins 20, 20b. The components 14 generate heat that is transferred to the corresponding heat sink bodies 8a, 8b or 8c. The air passes the fins 20a, 20b and is heated to about 71° C. by heat transferred therefrom, i.e. the heat sink bodies 8a, 8b, 8c are cooled by the air.

It should be noted that the bottom and the lid of the housing are active cooling surfaces connected to the heat sink bodies.

The pin formed fins shown in FIG. 8 may be exchanged to the form of fins shown in FIG. 7c.

By arranging the heat sink bodies on three sides of the housing, it has been possible to produce a compact rectifier that fits into a rack of standard size. By arranging three such layers on top on one another, it has been possible to produce a compact three phase rectifier.

Furthermore, a rectifier adapted to be assembled in an automated way is achieved.

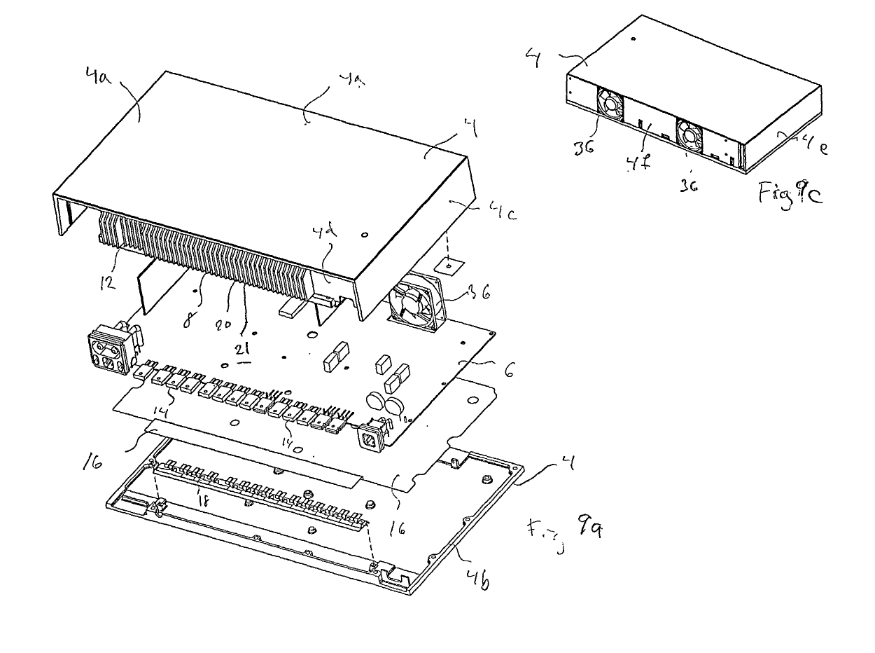

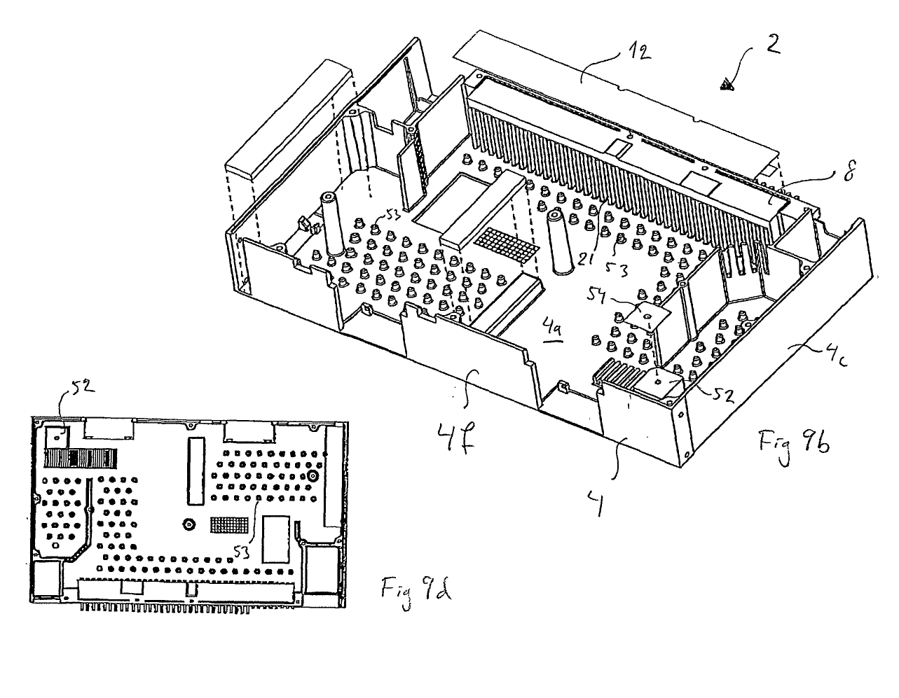

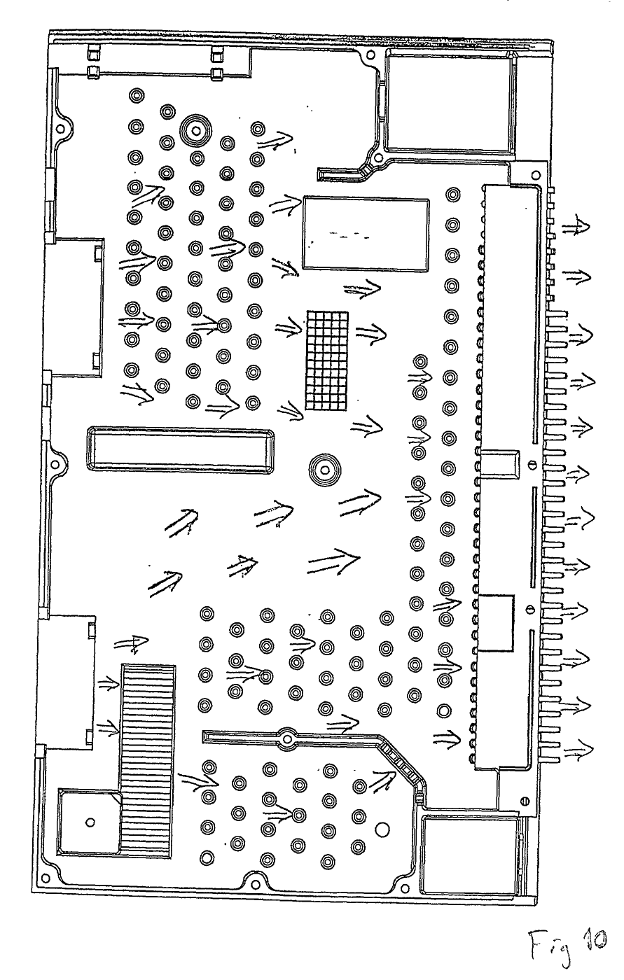

FIGS. 9a, 9b, 9c and 9d show a one phase rectifier from different angles.

The housing 4 is made of a bottom panel 4a, a lid 4b and side panels 4c, 4d, 4e, 4f. The side panels and the bottom panel constitute an integrated unit. All six sides of the housing 4 is made of an aluminium alloy.

The side panel 4f is provided with a pair of fans 36 for distribution of air inside the housing 4. The opposite panel 4d is provided with heat sink body 8 comprising a plurality of fins 20, divided by an air gap 21. One further heat sink body 52 in the form of a rectangular parallelepiped is integrated with the bottom panel 4a. It should thus be understood, that the whole housing 4 constitutes a heat sink for the over all cooling of the rectifier, whereas the heat sink bodies 8 and 52 constitute contacting members for heat transmission from the individual components. In order to improve the heat transfer properties of the bottom and the lid, they are provided with surface enlargements 53.

Closest to the heat sink body 8, an insulation member 12 is mounted, on top of which, the components 14 mounted on a printed circuit board 6 are arranged.

Closest to the lid 4a, the spring device 18 of the kind shown in FIG. 6d is arranged, on top of which an insulation member 16, covering a large part of the lid's inside, is arranged. On top of the heat transfer body 52, an insulation member 54 is arranged. The component to be cooled by the heat transfer body 52 has been omitted in the figure for reasons of clarity.

During assembly of the housing 4, the lid 4b, including the spring device 18 and the insulation member 16, are mounted above the printed circuit board 6. The strips 26 of the spring device 18 are adapted to contact each of the components 14.

The lid 4b is then screwed onto the side panels 4c-4f, during which operation, the strips 26 will be pressed towards the portion 32, so that a predetermined pressure is applied on each component, in the same manner as discussed above regarding the three phase rectifier.

Thus a very fast assembly of the rectifier is achieved, in particular as it is adapted to be assembled by an industrial robot.

FIG. 10 shows the air flow trough the rectifier of FIGS. 9a-9d. Air is drawn over the surface enlargements 53 and through the openings 21 of the heat sink body 8.

1. A housing for an electronic apparatus having heat generating components, such as a rectifier, comprising a bottom panel (4a), at least one side panel (4c, 4d, 4e, 4f) and a lid (4b), characterised in that the whole housing is adapted do constitute a heat sink.

2. A housing according to claim 1, wherein said bottom panel (4a) and said at least one side panel (4c, 4d, 4e, 4f) are formed in metal as an integrated first unit, wherein said first unit is adapted to receive said lid (4b) formed in metal and constituting a second unit.

3. A housing according to claim 1 or 2, wherein at least said first unit is provided with integrated surface enlargements (20, 52, 53) formed in one piece together with the rest of said first unit.

4. A housing according to claim 3, said surface enlargements (53) protrude from the interior surface of the first unit into the interior of the housing (4).

5. A housing according to claim 3 or 4, wherein at least one air inlet opening (at 36) is provided for allowing cooling air to enter the housing, and wherein at least one of said surface enlargements (20) is associated with at least one opening (21) for allowing air to pass through from the interior to the exterior of the housing.

6. A housing according to claim 5, wherein said air inlet opening is adapted to receive a fan (36) for drawing air through said air inlet opening and for creating a pressure higher than the atmospheric pressure inside the housing.

7. A housing according to anyone of claims 2-6, wherein it is made of an aluminium alloy.

8. A housing according to anyone of the preceding claims, wherein said bottom panel is substantially rectangular forming four edges, and wherein a side panel (4c, 4d, 4e 4f) is formed in one piece with the bottom panel along each edge, and wherein said side panels are formed as one piece.

9. A housing according to anyone of the preceding claims, wherein said lid (4b) is adapted to receive a spring device.

10. An electronic apparatus having heat generating components, such as a rectifier, comprising a housing according to anyone of the preceding claims and a printed circuit board (6).

11. An electronic apparatus according to claim 10, when dependent on claim 9, wherein said spring device is adapted to press the electronic component (14) towards a portion (8) of the first unit.

12. An electronic apparatus according to claim 10 or 11, wherein the printed circuit board is provided with a fan (36) to draw air into the interior of the housing and furthermore with an electric connector.

13. A method of assembling an electronic apparatus having heat generating components, such as a rectifier, characterised by selecting a housing (4) completely made of metal and comprising a lid (4b) and a first unit having a bottom panel (4a) and at least one side panel (4c, 4d, 4e, 4f), providing a printed circuit board (6) with components (14), providing said first unit with said printed circuit board (6), providing said first unit with a lid (4b), such that it covers the printed circuit board.

14. A method according to claim 13, including providing the lid (4b) with a spring device (18) before assembly and arranging the spring device such that it exerts a predetermined pressure on the components (14) after assembly.

15. A method according to claim 13 or 14, including providing the printed circuit board with at least one fan (36) and inserting the fan into an air inlet opening of said first unit during assembly.

16. A method according to anyone of claims 13 to 15, including providing the printed circuit board with an electric connector and inserting the fan into an air inlet opening of said first unit during assembly.
